(19) United States
(12) Patent Application Publication
(10) Pub. No.: US 2025/0031359 A1
(43) Pub. Date: Jan. 23, 2025

(54) SEMICONDUCTOR DEVICE

(71) Applicant: SAMSUNG ELECTRONICS CO., LTD., Suwon-si (KR)

(72) Inventors: Jee Woong Kim, Suwon-si (KR); Jin Kyu Kim, Suwon-si (KR); Yun Suk Nam, Suwon-si (KR); Kyo-Wook Lee, Suwon-si (KR)

(21) Appl. No.: 18/443,120

(22) Filed: Feb. 15, 2024

(30) Foreign Application Priority Data
Jul. 20, 2023 (KR) 10-2023-0094667

(51) Int. Cl. H10B 10/00

(52) U.S. Cl. CPC H10B 10/125

(57) ABSTRACT

The present disclosure relates to semiconductor devices, including a semiconductor device including a backside power delivery network (BSPDN). An example semiconductor device includes a substrate comprising a first surface and a second surface opposite to each other, a first active pattern on the first surface, a first gate structure intersecting the first active pattern, and first and second back wiring patterns disposed on the second surface at a same height from the substrate. The first back wiring pattern comprises a first extension portion and a second extension portion each extending in a first direction, and a connection portion extending in a second direction intersecting the first direction to connect the first extension portion to the second extension portion. The second back wiring pattern is spaced apart from the first extension portion in the second direction, and spaced apart from the connection portion in the first direction.

### CROSS-REFERENCE TO RELATED APPLICATION

This application claims priority from Korean Patent Application No. 10-2023-0094667 filed on Jul. 20, 2023, in the Korean Intellectual Property Office, and all the benefits accruing therefrom under 35 U.S.C. 119, the entire contents of which are herein incorporated by reference.

### BACKGROUND

Due to characteristics such as miniaturization, multifunctionality, and/or low manufacturing cost, a semiconductor device is in the spotlight as an important element in the electronic industry. The semiconductor devices may be divided into a semiconductor memory device for storing logic data, a semiconductor logic device for processing computation of logic data, a hybrid semiconductor device including a storage element and a logic element, and the like.

As the electronic industry advances, demands for characteristics of semiconductor devices increases. For example, demands for high reliability, high speed and/or multifunctionality, and the like for semiconductor devices are increasing. In order to meet these required characteristics, structures in semiconductor devices become increasingly complex and highly integrated.

### SUMMARY

The present disclosure relates to semiconductor devices, including a semiconductor device with improved design freedom and integration density, and are not restricted to the examples set forth herein. Other aspects of the present disclosure will become more apparent to one of ordinary skill in the art to which the present disclosure pertains by referencing the detailed description of the present disclosure given below.

In general, according to some aspects, a semiconductor device comprises a substrate comprising a first surface and a second surface opposite to each other, a first active pattern on the first surface of the substrate, a first gate structure intersecting the first active pattern, and a first back wiring pattern and a second back wiring pattern disposed at the same level, on the second surface of the substrate, wherein the first back wiring pattern comprises a first extension portion and a second extension portion each extending in a first direction, and a connection portion extending in a second direction intersecting the first direction to connect the first extension portion to the second extension portion, and the second back wiring pattern is spaced apart from the first extension portion in the second direction, and spaced apart from the connection portion in the first direction.

In general, according to some aspects, a semiconductor device comprises a substrate comprising a first surface and a second surface opposite to each other, a first active pattern and a second active pattern extending side by side, on the first surface of the substrate, a first gate structure intersecting the first active pattern and the second active pattern, first to third back wiring patterns disposed at the same level, and spaced apart from each other, on the second surface of the substrate, a first back source/drain contact connecting a first source/drain region of the first active pattern to the first back wiring pattern, a second back source/drain contact connecting a second source/drain region of the second active pattern to the second back wiring pattern, a fourth back wiring pattern more distant from the substrate than the first to third back wiring patterns, on the second surface of the substrate, and a first back via pattern connecting the second back wiring pattern to the fourth back wiring pattern, wherein the first back wiring pattern comprises a first extension portion and a second extension portion each extending in a first direction, and a connection portion extending in a second direction intersecting the first direction to connect the first extension portion to the second extension portion, and the connection portion is interposed between the second back wiring pattern and the third back wiring pattern in the first direction.

In general, according to some aspects, a semiconductor device comprises a substrate comprising a first surface and a second surface opposite to each other, a first active pattern on the first surface of the substrate, a first gate structure and a second gate structure extending parallel to each other, and each intersecting the first active pattern, a first source/drain contact connected to the first active pattern, between the first gate structure and the second gate structure, first to third back wiring patterns disposed at the same level, and spaced apart from each other, on the second surface of the substrate, a first back source/drain contact connecting the first active pattern to the first back wiring pattern, the first gate structure disposed between the first back source/drain contact and the first source/drain contact, a second back source/drain contact connecting the first active pattern to the second back wiring pattern, the second gate structure disposed between the second back source/drain contact and the first source/drain contact, a fourth back wiring pattern more distant from the substrate than the first to third back wiring patterns, on the second surface of the substrate, and a first back via pattern connecting the second back wiring pattern to the fourth back wiring pattern, wherein the first back wiring pattern comprises a first extension portion and a second extension portion each extending in a first direction, and a connection portion extending in a second direction intersecting the first direction to connect the first extension portion to the second extension portion, and the connection portion is interposed between the second back wiring pattern and the third back wiring pattern in the first direction.

### BRIEF DESCRIPTION OF THE DRAWINGS

The above and other aspects and features of the present disclosure will become more apparent by describing in detail example implementations thereof with reference to the attached drawings.

FIG. 1 is a circuit diagram illustrating an example of a semiconductor device.

FIG. 2 is a layout diagram illustrating an example of a semiconductor device.

FIG. 3 is a schematic cross-sectional view taken along line A-A of FIG. 2.

FIG. 4 is a schematic cross-sectional view taken along line B-B of FIG. 2.

FIG. 5 is a schematic cross-sectional view taken along line C-C of FIG. 2.

FIGS. 6 to 11 are layout diagrams for explaining an example of a semiconductor device.

FIG. 12 is a layout diagram illustrating an example of a semiconductor device.

FIG. 13 is a schematic cross-sectional view taken along line D-D of FIG. 12.

FIG. 14 is a schematic cross-sectional view taken along line E-E of FIG. 12.

FIG. 15 is a schematic cross-sectional view taken along line F-F of FIG. 12.

FIGS. 16 and 17 are layout diagrams for explaining an example of a semiconductor device.

FIG. 18 is a circuit diagram illustrating an example of a semiconductor device.

FIGS. 19 and 20 are layout diagrams for explaining an example of a semiconductor device.

FIG. 21 is a circuit diagram illustrating an example of a semiconductor device.

FIGS. 22 and 23 are layout diagrams for explaining an example of a semiconductor device.

### DETAILED DESCRIPTION

Although the terms first, second, etc. may be used herein to describe various elements or components, these elements or components should not be limited by these terms. These terms are used to distinguish one element or component from another element or component. Thus, a first element or component discussed below could be termed a second element or component without departing from the teachings of the present disclosure.

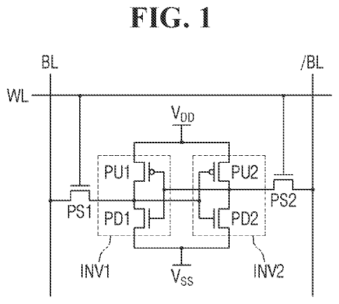

Hereinafter, a semiconductor device according to exemplary implementations will be described with reference to FIGS. 1 to 23. Hereinafter, implementations disclosed below mainly describe a static random access memory (SRAM) element as a semiconductor device, but this is only exemplary. Those skilled in the art will understand that the technical spirit of the present disclosure may be applied not only to SRAM elements but also to various other semiconductor devices such as logic elements.

FIG. 1 is a circuit diagram illustrating an example of a semiconductor device.

Referring to FIG. 1, a semiconductor device includes a pair of inverters INV1 and INV2 connected in parallel between a power node V_{DD} and a ground node V_{SS}, and a first pass transistor PS1 and a second pass transistor PS2 connected to output nodes of the respective inverters INV1 and INV2.

The first pass transistor PS1 may be connected to a bit line BL, and the second pass transistor PS2 may be connected to a complementary bit line/BL. Gates of the first pass transistor PS1 and the second pass transistor PS2 may be connected to a word line WL.

To configure one latch circuit, the input node of the first inverter INV1 may be connected to the output node of the second inverter INV2, and the input node of the second inverter INV2 may be connected to the output node of the first inverter INV1.

The first inverter INV1 may include a first pull-up transistor PU1 and a first pull-down transistor PD1 connected in series, and the second inverter INV2 may include a second pull-up transistor PU2 and a second pull-down transistor PD2 connected in series. The first pull-up transistor PU1 and the second pull-up transistor PU2 may be PFETs, and the first pull-down transistor PD1 and the second pull-down transistor PD2 may be NFETs.

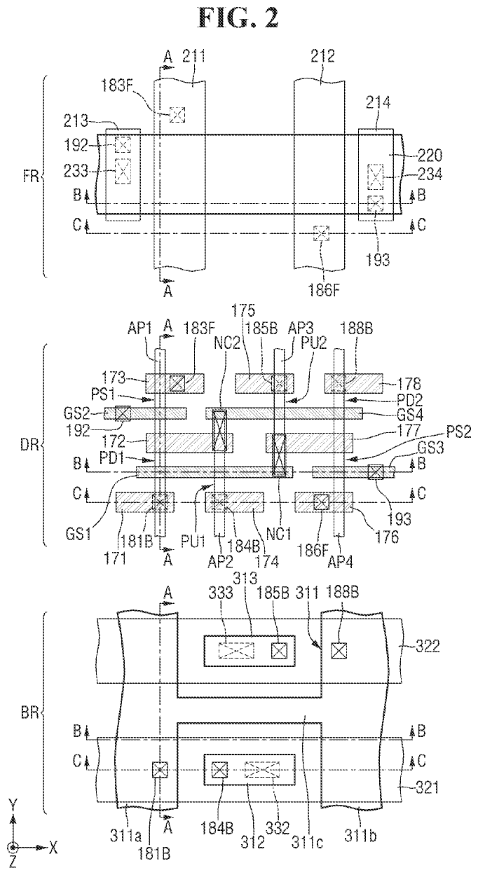

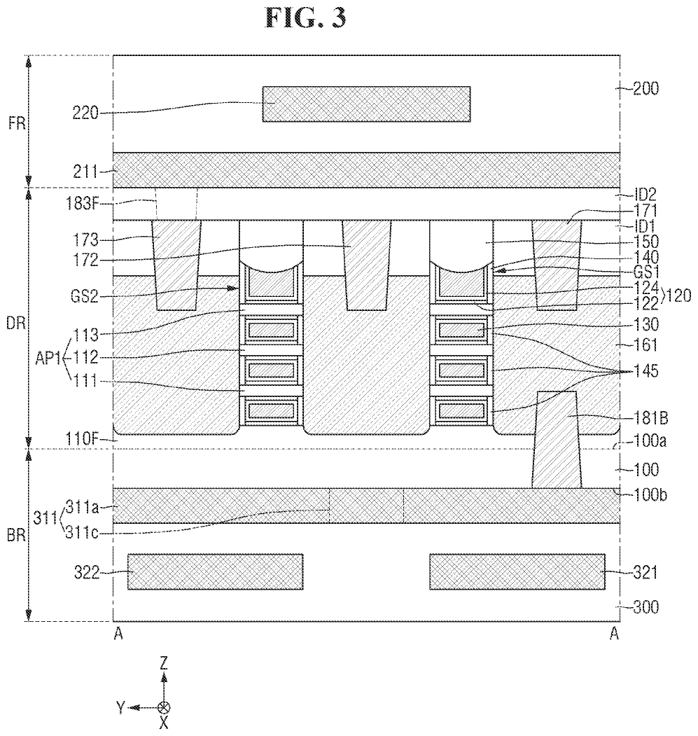

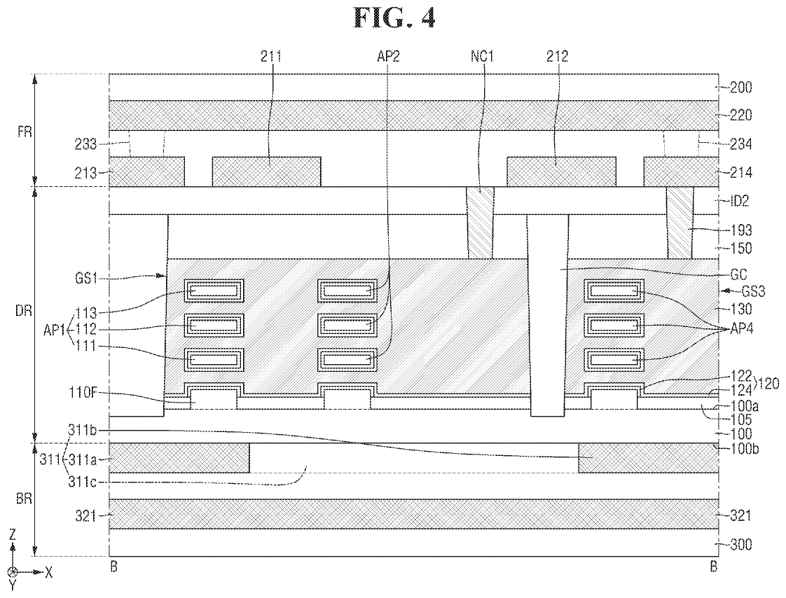

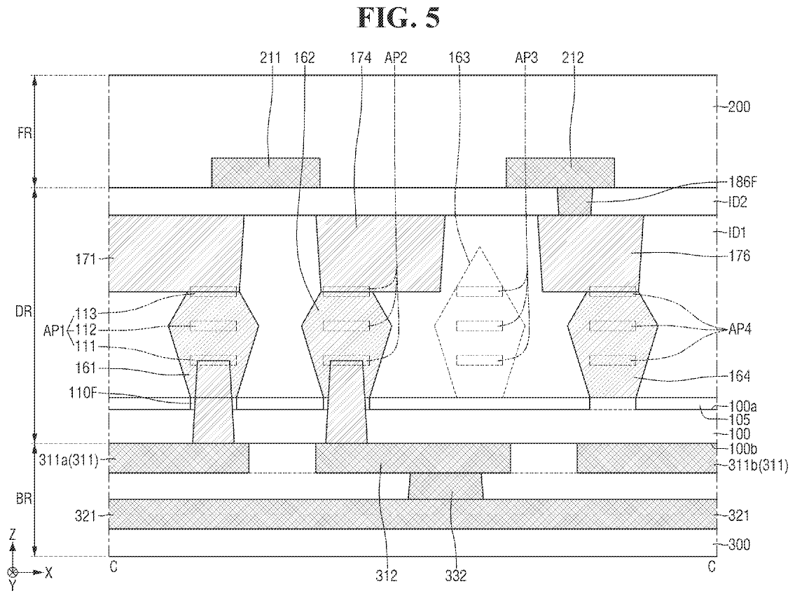

FIG. 2 is a layout diagram illustrating an example of a semiconductor device. FIG. 3 is a schematic cross-sectional view taken along line A-A of FIG. 2. FIG. 4 is a schematic cross-sectional view taken along line B-B of FIG. 2. FIG. 5 is a schematic cross-sectional view taken along line C-C of FIG. 2.

Referring to FIGS. 1 to 5, a semiconductor device includes an element region DR, a front region FR, and a back region BR.

The element region DR may include a substrate 100, a field insulating layer 105, first to fourth active patterns AP1 to AP4, first to fourth gate structures GS1 to GS4, source/drain contacts 171 to 178, a first shared contact NC1, a second shared contact NC2, a first interlayer insulating layer ID1, and a second interlayer insulating layer ID2.

The substrate 100 may be a bulk silicon or silicon-on-insulating layer (SOI) substrate. Alternatively, the substrate 100 may be a silicon substrate or may include other materials such as silicon germanium, silicon germanium on insulator (SGOI), indium antimonide, a lead tellurium compound, indium arsenide, indium phosphide, gallium arsenide, or gallium antimonide. Alternatively, the substrate 100 may have an epitaxial layer formed on a base substrate.

In some implementations, the substrate 100 may be an insulating substrate including an insulating material. For example, the substrate 100 may include at least one of silicon oxide, silicon oxynitride, silicon oxycarbonitride, or a combination thereof, but is not limited thereto. For example, the substrate 100 may include a silicon oxide layer.

The substrate 100 may include a first surface 100a and a second surface 100b opposite to each other. In the following implementations, the first surface 100a may also be referred to as a front side of the substrate 100, and the second surface 100b may also be referred to as a back side of the substrate 100.

The first to fourth active patterns AP1 to AP4 may be formed on the first surface 100a of the substrate 100. The first to fourth active patterns AP1 to AP4 may be spaced apart from each other and extend side by side in a first direction Y. For example, the first to fourth active patterns AP1 to AP4 may each be elongated in the first direction Y, and may be sequentially arranged along a second direction X intersecting the first direction Y.

Each of the first to fourth active patterns AP1 to AP4 may include elemental semiconductor materials such as silicon (Si) or germanium (Ge). Alternatively, each of the first to fourth active patterns AP1 to AP4 may include a compound semiconductor, for example, a group IV-IV compound semiconductor or a group III-V compound semiconductor. The group IV-IV compound semiconductor may be a binary compound or a ternary compound including at least two elements selected from the group consisting of carbon (C), silicon (Si), germanium (Ge) and tin (Sn), or the above-mentioned compound doped with a group IV element. The group III-V compound semiconductor may be, for example, a binary compound, a ternary compound or a quaternary compound formed by combining at least one of aluminum (Al), gallium (Ga) and indium (In) which are group III elements with at least one of phosphorus (P), arsenic (As) and antimonium (Sb) which are group V elements.

In some implementations, the first active pattern AP1 and the fourth active pattern AP4 may be used as a channel region of an NFET, and the second active pattern AP2 and the third active pattern AP3 may be used as a channel region of a PFET.

In some implementations, each of the first to fourth active patterns AP1 to AP4 may be sequentially stacked on the substrate 100 and may include a plurality of bridge patterns (e.g., first to third bridge patterns 111 to 113) spaced apart from each other. These first to fourth active patterns AP1 to AP4 may be used as a channel region of an MBCFET® including a multi-bridge channel. The number of bridge patterns included in each of the first to fourth active patterns AP1 to AP4 is only exemplary and is not limited thereto.

In some implementations, a fin-shaped pattern 110F may be formed between the substrate 100 and the first bridge pattern 111. The fin-shaped pattern 110F may protrude from a first surface 100a of the substrate 100 and extend in the first direction Y. In some implementations, the fin-shaped pattern 110F may be an insulating pattern including an insulating material.

A field insulating layer 105 may be formed on the substrate 100. In some implementations, the field insulating layer 105 may cover at least a part of a side surface of the fin-shaped pattern 110F. The field insulating layer 105 may include, for example, at least one of silicon oxide, silicon nitride, silicon oxynitride, or a combination thereof, but is not limited thereto.

The first to fourth gate structures GS1 to GS4 may be formed on the substrate 100 and the field insulating layer 105. The first to fourth gate structures GS1 to GS4 may be spaced apart from each other, and each may be elongated in the second direction X.

The first gate structure GS1 may intersect the first active pattern AP1 and the second active pattern AP2. For example, the bridge patterns 111 to 113 of the first active pattern AP1 and the second active pattern AP2 may extend in the first direction Y and penetrate the first gate structure GS1. The first gate structure GS1 may be provided as a gate of the first inverter INV1. For example, the first active pattern AP1 intersecting the first gate structure GS1 may be provided as a channel region of the first pull-down transistor PD1, and the second active pattern AP2 intersecting the first gate structure GS1 may be provided as a channel region of the first pull-up transistor PU1.

The second gate structure GS2 may be spaced apart from the first gate structure GS1 in the first direction Y. The second gate structure GS2 may extend parallel to the first gate structure GS1 and may intersect the first active pattern AP1. For example, the bridge patterns 111 to 113 of the second active pattern AP2 may extend in the first direction Y and penetrate the second gate structure GS2. The second gate structure GS2 may be provided as a gate of the first pass transistor PS1. For example, the first active pattern AP1 intersecting the second gate structure GS2 may be provided as a channel region of the first pass transistor PS1.

The third gate structure GS3 may be spaced apart from the first gate structure GS1 in the second direction X. The third gate structure GS3 may intersect the fourth active pattern AP4. For example, the bridge patterns 111 to 113 of the fourth active pattern AP4 may extend in the first direction Y and penetrate the third gate structure GS3. The third gate structure GS3 may be provided as a gate of the second pass transistor PS2. For example, the fourth active pattern AP4 intersecting the third gate structure GS3 may be provided as a channel region of the second pass transistor PS2.

The fourth gate structure GS4 may be spaced apart from the second gate structure GS2 in the second direction X. The fourth gate structure GS4 may extend parallel to the third gate structure GS3 and may intersect the third active pattern AP3 and the fourth active pattern AP4. For example, the bridge patterns 111 to 113 of the third active pattern AP3 and the fourth active pattern AP4 may extend in the first direction Y and penetrate the fourth gate structure GS4. The fourth gate structure GS4 may be provided as a gate of the second inverter INV2. For example, the fourth active pattern AP4 intersecting the fourth gate structure GS4 may be provided as a channel region of the second pull-down transistor PD2, and the third active pattern AP3 intersecting the fourth gate structure GS4 may be provided as a channel region of the second pull-up transistor PU2.

In some implementations, each of the first to fourth gate structures GS1 to GS4 may be isolated by an isolation pattern GC. For example, the isolation pattern GC may extend in the second direction X between the third active pattern AP3 and the fourth active pattern AP4, and may isolate the first gate structure GS1 from the third gate structure GS3. In addition, for example, the isolation pattern GC may extend in the second direction X between the first active pattern AP1 and the second active pattern AP2 and may isolate the second gate structure GS2 from the fourth gate structure GS4.

The isolation pattern GC may include an insulating material, for example, at least one of silicon oxide, silicon nitride, silicon oxynitride, silicon oxycarbide, silicon boron nitride, silicon boron carbonitride, silicon oxycarbonitride, or a combination thereof, but is not limited thereto.

Each of the first to fourth gate structures GS1 to GS4 may include a gate dielectric layer 120, a gate electrode 130, a gate spacer 140, and a gate capping layer 150.

The gate dielectric layer 120 may be interposed between each of the first to fourth active patterns AP1 to AP4 and the gate electrode 130. The gate dielectric layer 120 may include a dielectric material, for example, at least one of silicon oxide, silicon oxynitride, silicon nitride, or a high-k material having a higher dielectric constant than silicon oxide. The high-k material may include, for example, at least one selected from the group consisting of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate and a combination thereof, but is not limited thereto.

The gate electrode 130 may be elongated in the second direction X and intersect the first to fourth active patterns AP1 to AP4. Each of the bridge patterns 111 to 113 of the first to fourth active patterns AP1 to AP4 may extend in the first direction Y and penetrate the gate electrode 130. The gate electrode 130 may include a conductive material, for example, at least one of TiN, WN, TaN, Ru, TiC, TaC, Ti, Ag, Al, TiAl, TiAlN, TiAlC, TaCN, TaSiN, Mn, Zr, W, Al or a combination thereof, but is not limited thereto. The gate electrode 130 may be formed, for example, by a replacement process, but is not limited thereto.

Although the gate electrode 130 is illustrated as a single layer, this is only exemplary, and the gate electrode 130 may be a multilayer formed by stacking a plurality of conductive layers. For example, the gate electrode 130 may include a work function adjusting layer to adjust the work function and a filling conductive layer to fill a space formed by the work function adjusting layer. The work function adjusting layer may include at least one of TiN, TaN, TiC, TaC, TiAIC or a combination thereof, for example. The filling conductive layer may include, for example, W or Al.

The gate spacer 140 may extend along the side surface of the gate electrode 130. Each of the bridge patterns 111 to 113 of the first to fourth active patterns AP1 to AP4 may extend in the first direction Y and penetrate the gate spacer 140. The gate spacer 140 may include an insulating material, for example, at least one of silicon oxide, silicon nitride, silicon oxynitride, silicon oxycarbide, silicon boron nitride, silicon boron carbonitride, silicon oxycarbonitride, or a combination thereof, but is not limited thereto.

In some implementations, the gate dielectric layer 120 may include an interface layer 122 and a high dielectric layer 124 sequentially stacked on the first to fourth active patterns AP1 to AP4.

The interface layer 122 may surround the perimeter of each of the bridge patterns 111 to 113. For example, the interface layer 122 may conformally extend along the perimeter of each of the bridge patterns 111 to 113. In some implementations, the interface layer 122 may include an oxide layer formed by oxidizing surfaces of each of the bridge patterns 111 to 113. For example, when each of the bridge patterns 111 to 113 includes silicon (Si), the interface layer 122 may include a silicon oxide layer.

The high dielectric layer 124 may surround the perimeter of the interface layer 122. In addition, a part of the high dielectric layer 124 may be interposed between the gate electrode 130 and the gate spacer 140. For example, the high dielectric layer 124 may conformally extend along the perimeter of the interface layer 122 and the profile of the inner surface of the gate spacer 140. In addition, the high dielectric layer 124 may further extend along the top surface of the field insulating layer 105.

In some implementations, the high dielectric layer 124 may include a high-k material having a higher dielectric constant than silicon oxide. The high-k material may include, for example, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), or combinations thereof, but is not limited thereto.

The gate capping layer 150 may extend along the top surface of the gate electrode 130. The gate capping layer 150 may include an insulating material, for example, at least one of silicon oxide, silicon nitride, silicon oxynitride, silicon oxycarbide, silicon boron nitride, silicon boron carbonitride, silicon oxycarbonitride, or a combination thereof, but is not limited thereto.

The first to fourth active patterns AP1 to AP4 may include first to fourth source/drain regions 161 to 164. The first to fourth source/drain regions 161 to 164 may be formed in the first to fourth active patterns AP1 to AP4 on side surfaces of the first to fourth gate structures GS1 to GS4. The bridge patterns 111 to 113 of the first to fourth active patterns AP1 to AP4 may penetrate the gate electrode 130 and the gate spacer 140 to be connected with the first to fourth source/drain regions 161 to 164. The first to fourth source/drain regions 161 to 164 may be electrically isolated from the gate electrode 130 by the gate spacer 140. In the implementations illustrated herein, the phrase source/drain region may be understood to mean a source terminal region or a drain terminal region of a transistor.

In some implementations, each of the first to fourth source/drain regions 161 to 164 may include an epitaxial layer doped with impurities. For example, the first to fourth source/drain regions 161 to 164 may include epitaxial patterns grown from the first to fourth active patterns AP1 to AP4 by an epitaxial growth method.

The source/drain contacts 171 to 178 may be connected to the first to fourth active patterns AP1 to AP4. For example, the source/drain contacts 171 to 178 may be connected to the first to fourth source/drain regions 161 to 164. The shapes, dispositions, or the like of the source/drain contacts 171 to 178 are only exemplary, and are not limited to those illustrated.

For example, the first to third source/drain contacts 171 to 173 respectively connected to the first source/drain region 161 of the first active pattern AP1 may be formed. The first to third source/drain contacts 171 to 173 may be sequentially arranged along the first direction Y. The second source/drain contact 172 may be interposed between the first gate structure GS1 and the second gate structure GS2. The first gate structure GS1 may be interposed between the first source/drain contact 171 and the second source/drain contact 172. The second gate structure GS2 may be interposed between the second source/drain contact 172 and the third source/drain contact 173.

For example, the second and fourth source/drain contacts 172 and 174 respectively connected to the second source/drain region 162 of the second active pattern AP2 may be formed. The second source/drain contact 172 may extend in the second direction X and connect the first source/drain region 161 of the first active pattern AP1 to the second source/drain region 162 of the second active pattern AP2. The first gate structure GS1 may be interposed between the second source/drain contact 172 and the fourth source/drain contact 174.

For example, sixth to eighth source/drain contacts 176 to 178 respectively connected to the fourth source/drain region 164 of the fourth active pattern AP4 may be formed. The sixth to eighth source/drain contacts 176 to 178 may be sequentially arranged along the first direction Y. A seventh source/drain contact 177 may be interposed between the third gate structure GS3 and the fourth gate structure GS4. The third gate structure GS3 may be interposed between the sixth source/drain contact 176 and the seventh source/drain contact 177. The fourth gate structure GS4 may be interposed between the seventh source/drain contact 177 and the eighth source/drain contact 178.

For example, the fifth and seventh source/drain contacts 175 and 177 respectively connected to the third source/drain region 163 of the third active pattern AP3 may be formed. The fifth source/drain contact 175 may extend in the second direction X and connect the third source/drain region 163 of the third active pattern AP3 to the fourth source/drain region 164 of the fourth active pattern AP4. The fourth gate structure GS4 may be interposed between the fifth source/drain contact 175 and the seventh source/drain contact 177.

The first shared contact NC1 may electrically connect the first gate structure GS1 to the seventh source/drain contact 177. For example, the first shared contact NC1 may extend in the first direction Y and may connect the gate electrode 130 of the first gate structure GS1 to the seventh source/drain contact 177. Through the first shared contact NC1, the input node (i.e., the first gate structure GS1) of the first inverter INV1 may be connected to the output node (i.e., the seventh source/drain contact 177) of the second inverter INV2.

The second shared contact NC2 may electrically connect the fourth gate structure GS4 to the second source/drain contact 172. For example, the second shared contact NC2 may extend in the first direction Y and may connect the gate electrode 130 of the fourth gate structure GS4 to the second source/drain contact 172. Through the second shared contact NC2, the input node (i.e., the fourth gate structure GS4) of the second inverter INV2 may be connected to the output node (i.e., the second source/drain contact 172) of the first inverter INV1.

The first interlayer insulating layer ID1 may fill spaces on side surfaces of the first to fourth gate structures GS1 to GS4. For example, the first interlayer insulating layer ID1 may cover the first to fourth source/drain regions 161 to 164. The second interlayer insulating layer ID2 may cover the first to fourth gate structures GS1 to GS4 and the first interlayer insulating layer ID1.

Each of the first interlayer insulating layer ID1 and the second interlayer insulating layer ID2 may include, for example, at least one of silicon oxide, silicon nitride, silicon oxynitride, silicon oxycarbide, silicon boron nitride, silicon carbonitride, silicon oxycarbonitride, or a low-k material having a smaller dielectric constant than silicon oxide, but is not limited thereto.

The front region FR may be formed on the first surface 100a of the substrate 100. The front region FR may include first level front wiring patterns 211 to 214 and second level front wiring patterns 220. For example, a front inter-wiring insulating layer 200 may be formed on the second interlayer insulating layer ID2. The first level front wiring patterns 211 to 214 and the second level front wiring patterns 220 may be formed in the front inter-wiring insulating layer 200 and insulated from each other.

The first level front wiring patterns 211 to 214 may be disposed at the same level and may be spaced apart from each other. The second level front wiring patterns 220 may be disposed at the same level and may be spaced apart from each other. In the present specification, being disposed “at the same level” means being disposed at the same height in a third direction Z with respect to the substrate 100. The second level front wiring patterns 220 may be disposed at a higher level than the first level front wiring patterns 211 to 214. For example, the second level front wiring patterns 220 may be more distant from the substrate 100 in the third direction Z than the first level front wiring patterns 211 to 214.

In some implementations, the first level front wiring patterns 211 to 214 may include a first front wiring pattern 211, a second front wiring pattern 212, a third front wiring pattern 213, and a fourth front wiring pattern 214. In some implementations, the second level front wiring patterns 220 may include a fifth front wiring pattern 220.

The first front wiring pattern 211 may be connected to the third source/drain contact 173. For example, a first contact via 183F, which penetrates the second interlayer insulating layer ID2 to connect the third source/drain contact 173 to the first front wiring pattern 211, may be formed. The first front wiring pattern 211 may be provided as the bit line BL and may be connected to the first pass transistor PS1 through the third source/drain contact 173. In some implementations, the first front wiring pattern 211 may be elongated in the first direction Y.

The second front wiring pattern 212 may be connected to the sixth source/drain contact 176. For example, a second contact via 186F, which penetrates the second interlayer insulating layer ID2 to connect the sixth source/drain contact 176 to the second front wiring pattern 212, may be formed. The second front wiring pattern 212 may be provided as the complementary bit line/BL and may be connected to the second pass transistor PS2 through the sixth source/drain contact 176. In some implementations, the second front wiring pattern 212 may be elongated in the first direction Y.

The third front wiring pattern 213 may be connected to the second gate structure GS2. For example, a first gate contact 192, which penetrates the second interlayer insulating layer ID2 and the gate capping layer 150 to connect the gate electrode 130 of the second gate structure GS2 to the third front wiring pattern 213, may be formed.

The fourth front wiring pattern 214 may be connected to the third gate structure GS3. For example, a second gate contact 193, which penetrates the second interlayer insulating layer ID2 and the gate capping layer 150 to connect the gate electrode 130 of the third gate structure GS3 to the fourth front wiring pattern 214, may be formed.

In some implementations, the lengths of the third front wiring pattern 213 and the fourth front wiring pattern 214 extending in the first direction Y may be smaller than the lengths of the first front wiring pattern 211 and the second front wiring pattern 212 extending in the first direction Y.

The fifth front wiring pattern 220 may be connected to the third front wiring pattern 213 and the fourth front wiring pattern 214. For example, a first front via pattern 233, which extends in the third direction Z within the front inter-wiring insulating layer 200 and connects the third front wiring pattern 213 to the fifth front wiring pattern 220, may be formed. In addition, for example, a second front via pattern 234, which extends in the third direction Z within the front inter-wiring insulating layer 200 and connects the fourth front wiring pattern 214 to the fifth front wiring pattern 220, may be formed. The fifth front wiring pattern 220 may be provided as the word line WL, and may be connected to the gate of the first pass transistor PS1 through the third front wiring pattern 213, and may be connected to the gate of the second pass transistor PS2 through the fourth front wiring pattern 214. In some implementations, the fifth front wiring pattern 220 may be elongated in the second direction X.

The back region BR may be formed on the second surface 100b of the substrate 100. The back region BR may include first level back wiring patterns 311 to 313 and second level back wiring patterns 321 and 322. For example, a back inter-wiring insulating layer 300 may be formed on the second surface 100b of the substrate 100. The first level back wiring patterns 311 to 313 and the second level back wiring patterns 321 and 322 may be formed in the back inter-wiring insulating layer 300 and insulated from each other.

The first level back wiring patterns 311 to 313 may be disposed at the same level and may be spaced apart from each other. The second level back wiring patterns 321 and 322 may be disposed at the same level and spaced apart from each other. The second level back wiring patterns 321 and 322 may be disposed at a higher level than the first level back wiring patterns 311 to 313. For example, the second level back wiring patterns 321 and 322 may be more distant from the substrate 100 in the third direction Z than the first level back wiring patterns 311 to 313.

In some implementations, the first level back wiring patterns 311 to 313 may include a first back wiring pattern 311, a second back wiring pattern 312, and a third back wiring pattern 313. In some implementations, the second level back wiring patterns 321 and 322 may include a fourth back wiring pattern 321 and a fifth back wiring pattern 322.

The first back wiring pattern 311 may include a first extension portion 311a, a second extension portion 311b, and a connection portion 311c. Each of the first extension portion 311a and the second extension portion 311b may extend in the first direction Y. The connection portion 311c may extend in the second direction X to connect the first extension portion 311a to the second extension portion 311b.

The second back wiring pattern 312 may be spaced apart from the first extension portion 311a in the second direction X and may be spaced apart from the connection portion 311c in the first direction Y. The third back wiring pattern 313 may be spaced apart from the second extension portion 311b in the second direction X and may be spaced apart from the connection portion 311c in the first direction Y. The connection portion 311c may be interposed between the second back wiring pattern 312 and the third back wiring pattern 313.

In some implementations, each of the first extension portion 311a and the second extension portion 311b may be elongated in the first direction Y. For example, as illustrated, the second back wiring pattern 312 may be interposed between the first extension portion 311a and the second extension portion 311b in the second direction X, and the third back wiring pattern 313 may be interposed between the first extension portion 311a and the second extension portion 311b in the second direction X. The first extension portion 311a, the second extension portion 311b, and the connection portion 311c may be integrally formed to provide the first back wiring pattern 311 having an approximate ‘H’ shape. Each of the second back wiring pattern 312 and the third back wiring pattern 313 may be an island-shaped pattern disposed within an empty area of the first back wiring pattern 311 having the approximate ‘H’ shape.

The first back wiring pattern 311 may be connected to the first source/drain region 161 of the first active pattern AP1 with the first gate structure GS1 disposed between the first source/drain region 161 and the second source/drain contact 172. For example, a first back source/drain contact 181B with the first gate structure GS1 disposed between the first back source/drain contact 181B and the second source/drain contact 172 may be formed. The first back source/drain contact 181B may penetrate the substrate 100 and may connect the first source/drain region 161 of the first active pattern AP1 to the first extension portion 311a. The first back wiring pattern 311 may be provided as the ground node V_{SS} for applying a first power voltage to the first pull-down transistor PD1.

In addition, the first back wiring pattern 311 may be connected to the fourth source/drain region 164 of the fourth active pattern AP4 with the fourth gate structure GS4 disposed between the fourth source/drain region 164 and the seventh source/drain contact 177. For example, a second back source/drain contact 188B with the fourth gate structure GS4 disposed between the second back source/drain contact 188B and the seventh source/drain contact 177 may be formed. The second back source/drain contact 188B may penetrate the substrate 100 and may connect the fourth source/drain region 164 of the fourth active pattern AP4 to the second extension portion 311b. The first back wiring pattern 311 may be provided as the ground node V_{SS} for applying the first power voltage to the second pull-down transistor PD2.

The second back wiring pattern 312 may be connected to the second source/drain region 162 of the second active pattern AP2 with the first gate structure GS1 disposed between the second source/drain region 162 and the second source/drain contact 172. For example, a third back source/drain contact 184B with the first gate structure GS1 disposed between the third back source/drain contact 184B and the second source/drain contact 172 may be formed. The third back source/drain contact 184B may penetrate the substrate 100 and may connect the second source/drain region 162 of the second active pattern AP2 to the second back wiring pattern 312.

The third back wiring pattern 313 may be connected to the third source/drain region 163 of the third active pattern AP3 with the fourth gate structure GS4 disposed between the third source/drain region 163 and the seventh source/drain contact 177. For example, a fourth back source/drain contact 185B with the fourth gate structure GS4 disposed between the fourth back source/drain contact 185B and the seventh source/drain contact 177 may be formed. The fourth back source/drain contact 185B may penetrate the substrate 100 and may connect the third source/drain region 163 of the third active pattern AP3 to the third back wiring pattern 313.

The fourth back wiring pattern 321 may be connected to the second back wiring pattern 312. For example, a first back via pattern 332, which extends in the third direction Z within the back inter-wiring insulating layer 300 and connects the second back wiring pattern 312 to the fourth back wiring pattern 321, may be formed. The fourth back wiring pattern 321 may be provided as the power node V_{DD} for applying a second power voltage different from the first power voltage to the first pull-up transistor PU1 through the second back wiring pattern 312. In some implementations, the fourth back wiring pattern 321 may be elongated in the second direction X.

The fifth back wiring pattern 322 may be connected to the third back wiring pattern 313. For example, a second back via pattern 333, which extends in the third direction Z within the back inter-wiring insulating layer 300 and connects the third back wiring pattern 313 to the fifth back wiring pattern 322, may be formed. The fifth back wiring pattern 322 may be provided as the power node V_{DD} for applying the second power voltage to the second pull-up transistor PU2 through the third back wiring pattern 313. In some implementations, the fifth back wiring pattern 322 may be elongated in the second direction X.

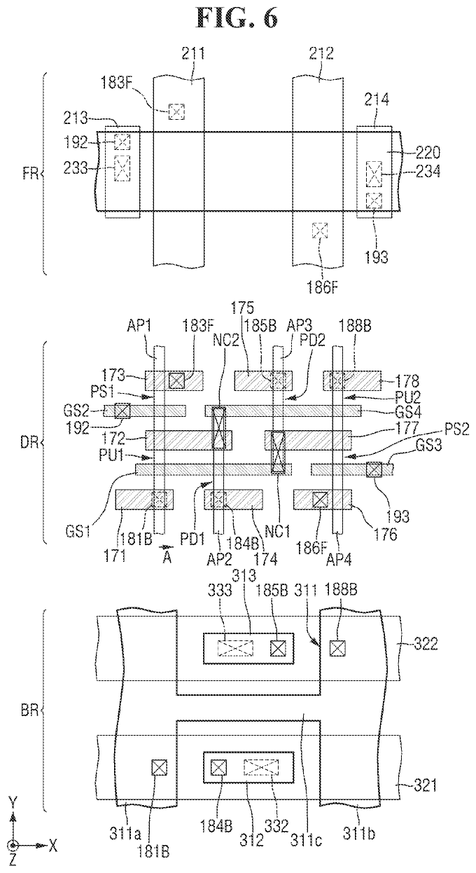

FIGS. 6 to 11 are layout diagrams for explaining an example of a semiconductor device. For simplicity of description, redundant parts of the description made with reference to FIGS. 1 to 5 may be recapitulated or omitted.

Referring to FIGS. 1 and 6, in the semiconductor device, the first active pattern AP1 and the fourth active pattern AP4 are used as a channel region of a PFET, and the second active pattern AP2 and the third active pattern AP3 are used as a channel region of an NFET.

The first active pattern AP1 intersecting the first gate structure GS1 may be provided as the channel region of the first pull-up transistor PU1, and the second active pattern AP2 intersecting the first gate structure GS1 may be provided as the channel region of the first pull-down transistor PD1.

The fourth active pattern AP4 intersecting the fourth gate structure GS4 may be provided as the channel region of the second pull-up transistor PU2, and the third active pattern AP3 intersecting the fourth gate structure GS4 may be provided as the channel region of the second pull-down transistor PD2.

The first back wiring pattern 311 may be provided as the power node V_{DD} for applying the second power voltage to the first pull-up transistor PU1 and the second pull-up transistor PU2.

The fourth back wiring pattern 321 may be provided as the ground node V_{SS} for applying the first power voltage to the first pull-down transistor PD1 through the second back wiring pattern 312.

The fifth back wiring pattern 322 may be provided as the ground node V_{SS} for applying the first power voltage to the second pull-down transistor PD2 through the third back wiring pattern 313.

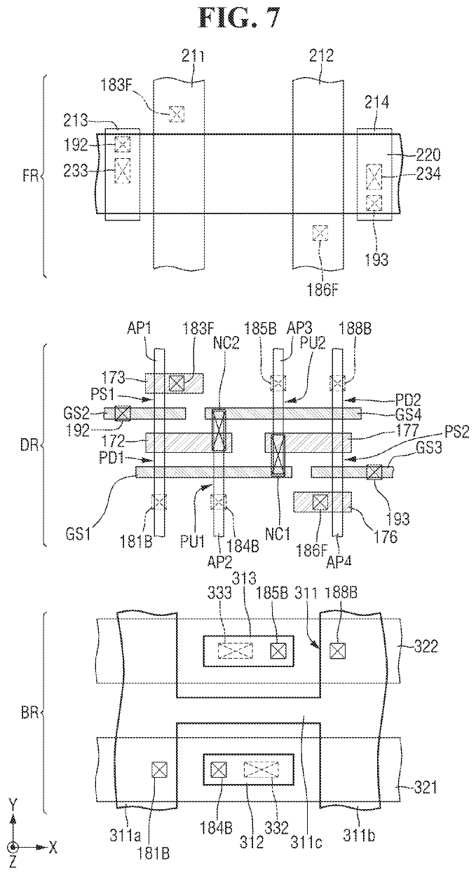

Referring to FIGS. 1 and 7, the semiconductor device includes the source/drain contacts 172, 173, 176, and 177.

The source/drain contacts 172, 173, 176, and 177 may not overlap the back source/drain contacts 181B, 184B, 185B, and 188B in the third direction Z. For example, the first source/drain contact 171, the fourth source/drain contact 174, the fifth source/drain contact 175, and the eighth source/drain contact 178 of FIG. 2 may be omitted as dummy source/drain contacts.

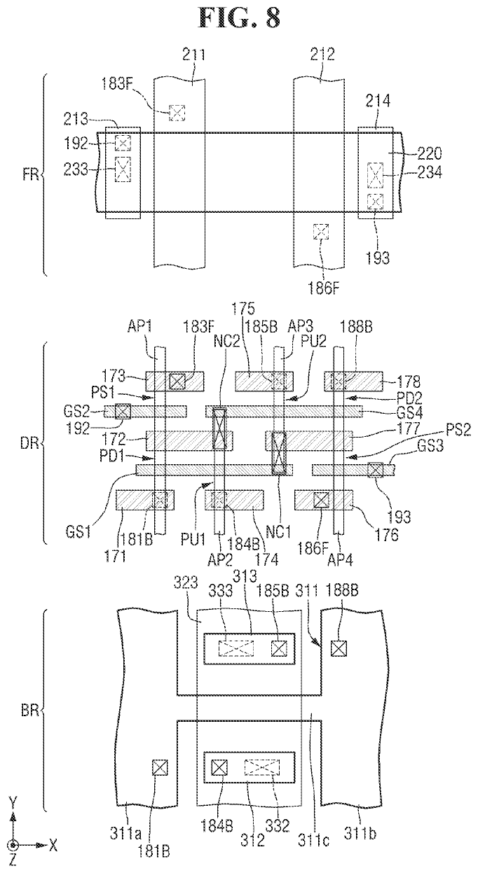

Referring to FIGS. 1 and 8, the semiconductor device includes second level back wiring patterns 323 including a sixth back wiring pattern 323.

The sixth back wiring pattern 323 may be connected to the second back wiring pattern 312 and the third back wiring pattern 313. For example, the first back via pattern 332 may connect the second back wiring pattern 312 to the sixth back wiring pattern 323, and the second back via pattern 333 may connect the third back wiring pattern 313 to the sixth back wiring pattern 323. The sixth back wiring pattern 323 may be provided as the power node V_{DD} for applying the second power voltage to the first pull-up transistor PU1 and the second pull-up transistor PU2 through the second back wiring pattern 312 and the third back wiring pattern 313. In some implementations, the sixth back wiring pattern 323 may be elongated in the first direction Y.

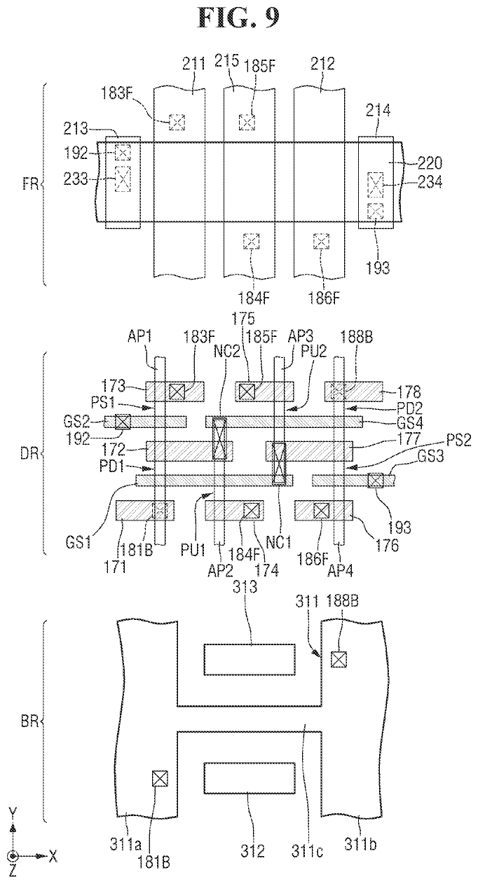

Referring to FIGS. 1 and 9, the semiconductor device includes first level front wiring patterns 211 to 215 including a sixth front wiring pattern 215.

The sixth front wiring pattern 215 may be connected to the fourth source/drain contact 174 and the fifth source/drain contact 175. For example, a third contact via 184F may be formed to connect the fourth source/drain contact 174 to the sixth front wiring pattern 215. In addition, for example, a fourth contact via 185F may be formed to connect the fifth source/drain contact 175 to the sixth front wiring pattern 215. The sixth front wiring pattern 215 may be provided as the power node V_{DD} for applying the second power voltage to the first pull-up transistor PU1 and the second pull-up transistor PU2 through the fourth source/drain contact 174 and the fifth source/drain contact 175. In some implementations, the sixth front wiring pattern 215 may be elongated in the first direction Y.

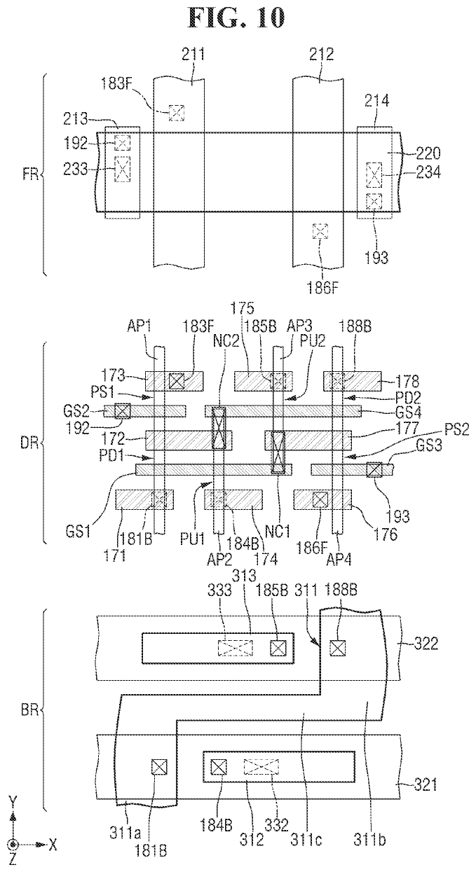

Referring to FIGS. 1 and 10, in the semiconductor device, the first extension portion 311a and the second extension portion 311b extend in opposite directions with respect to the connection portion 311c.

For example, as shown in the drawing, the second back wiring pattern 312 may not overlap the second extension portion 311b in the second direction X, and the third back wiring pattern 313 may not overlap the first extension portion 311a in the second direction X. The first extension portion 311a, the second extension portion 311b, and the connection portion 311c may be integrally formed to provide the first back wiring pattern 311 having an approximate ‘right-angled Z’ shape. The second back wiring pattern 312 and the third back wiring pattern 313 may each be an island-shaped pattern disposed in an empty area of the first back wiring pattern 311 having an approximate ‘right-angled Z’ shape.

In some implementations, a part of the second back wiring pattern 312 may overlap the second extension portion 311b in the first direction Y. In some implementations, a part of the third back wiring pattern 313 may overlap the first extension portion 311a in the first direction Y.

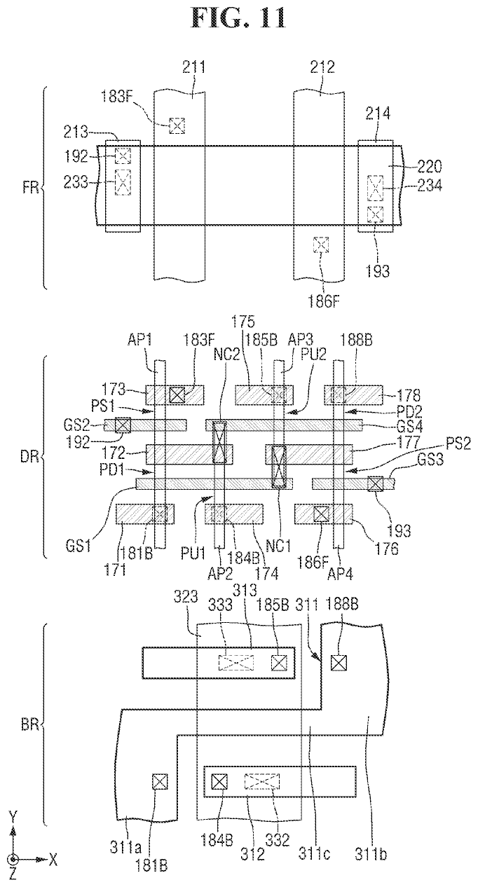

Referring to FIGS. 1 and 11, the semiconductor device includes the first level back wiring patterns 311 to 313 including the first back wiring pattern 311, and the second level back wiring patterns 323 including the sixth back wiring pattern 323. The first back wiring pattern 311 is similar to that described above with reference to FIG. 10, and thus a detailed description thereof is omitted below. The sixth back wiring pattern 323 is similar to that described above with reference to FIG. 8, and thus a detailed description thereof is omitted below.

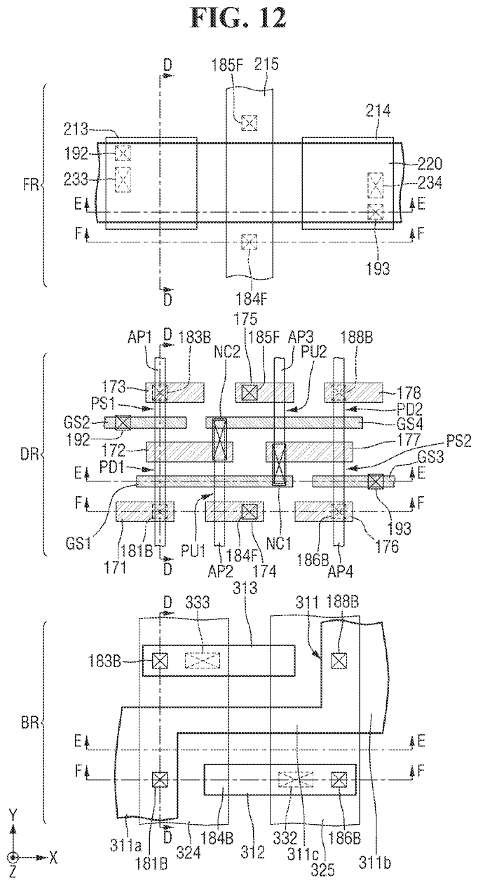

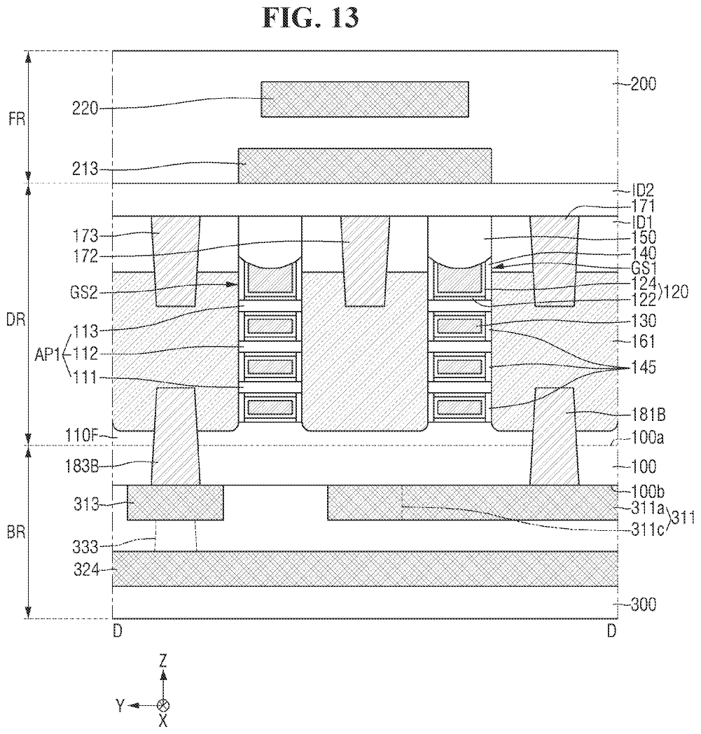

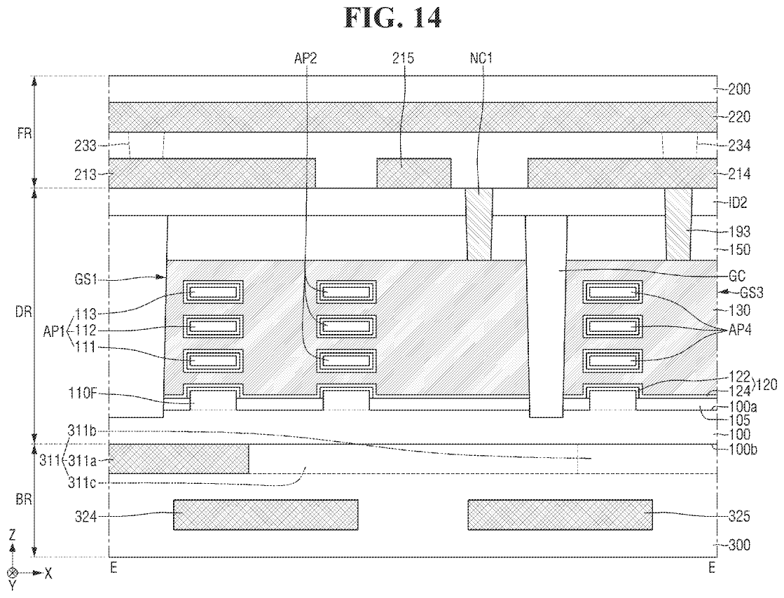

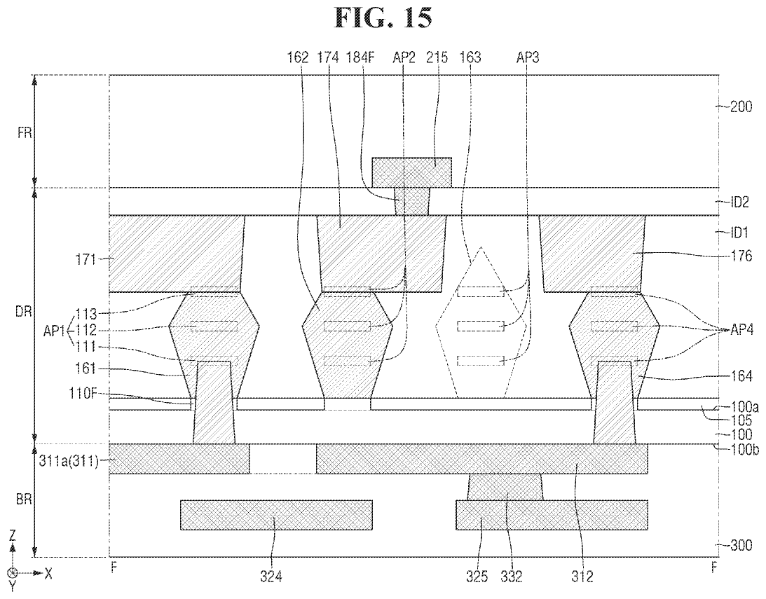

FIG. 12 is a layout diagram illustrating an example of a semiconductor device. FIG. 13 is an example schematic cross-sectional view taken along line D-D of FIG. 12. FIG. 14 is an example schematic cross-sectional view taken along line E-E of FIG. 12. FIG. 15 is an example schematic cross-sectional view taken along line F-F of FIG. 12. For simplicity of description, redundant parts of the description made with reference to FIGS. 1 to 11 may be recapitulated or omitted hereinbelow.

Referring to FIGS. 1 and 12 to 15, the semiconductor device includes the first level front wiring patterns 213 to 215, the second level front wiring patterns 220, the first level back wiring patterns 311 to 313, and second level back wiring patterns 324 and 325.

The first level front wiring patterns 213 to 215 may include the third front wiring pattern 213, the fourth front wiring pattern 214, and the sixth front wiring pattern 215. For example, the first front wiring pattern 211 and the second front wiring pattern 212 of FIG. 2 may be omitted. As the first front wiring pattern 211 and the second front wiring pattern 212 are omitted, the third front wiring pattern 213 and the fourth front wiring pattern 214 may each be formed to be relatively large in the second direction X. The sixth front wiring pattern 215 is similar to that described above with reference to FIG. 9, and thus a detailed description thereof is omitted.

The first level back wiring patterns 311 to 313 may include the first back wiring pattern 311, the second back wiring pattern 312, and the third back wiring pattern 313. The second level back wiring patterns 324 and 325 may include a seventh back wiring pattern 324 and an eighth back wiring pattern 325. The first back wiring pattern 311 is similar to that described above with reference to FIG. 10, and thus a detailed description thereof is omitted.

The second back wiring pattern 312 may be connected to the fourth source/drain region 164 of the fourth active pattern AP4 with the third gate structure GS3 disposed between the fourth source/drain region 164 and the seventh source/drain contact 177. For example, a fifth back source/drain contact 186B with the third gate structure GS3 disposed between the fifth back source/drain contact 186B and the seventh source/drain contact 177 may be formed. The fifth back source/drain contact 186B may penetrate the substrate 100 and connect the fourth source/drain region 164 of the fourth active pattern AP4 to the second back wiring pattern 312.

The third back wiring pattern 313 may be connected to the first source/drain region 161 of the first active pattern AP1 with the second gate structure GS2 disposed between the first source/drain region 161 and the second source/drain contact 172. For example, a sixth back source/drain contact 183B with the second gate structure GS2 disposed between the sixth back source/drain contact 183B and the second source/drain contact 172 may be formed. The sixth back source/drain contact 183B may penetrate the substrate 100 and connect the first source/drain region 161 of the first active pattern AP1 to the third back wiring pattern 313.

The seventh back wiring pattern 324 may be connected to the third back wiring pattern 313. For example, the second back via pattern 333 may connect the third back wiring pattern 313 to the seventh back wiring pattern 324. The seventh back wiring pattern 324 may be provided as the bit line BL and may be connected to the first pass transistor PS1 through the third back wiring pattern 313. In some implementations, the seventh back wiring pattern 324 may be elongated in the first direction Y.

The eighth back wiring pattern 325 may be connected to the second back wiring pattern 312. For example, the first back via pattern 332 may connect the second back wiring pattern 312 to the eighth back wiring pattern 325. The eighth back wiring pattern 325 may be provided as the complementary bit line/BL and may be connected to the second pass transistor PS2 through the second back wiring pattern 312. In some implementations, the eighth back wiring pattern 325 may be elongated in the first direction Y.

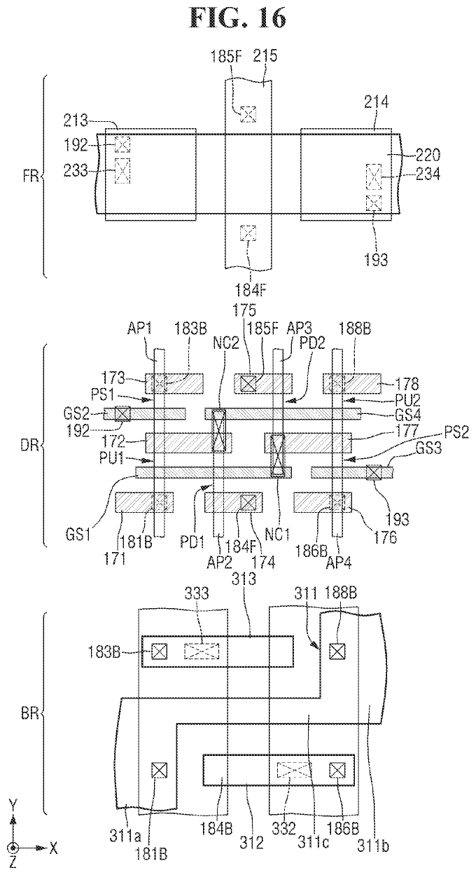

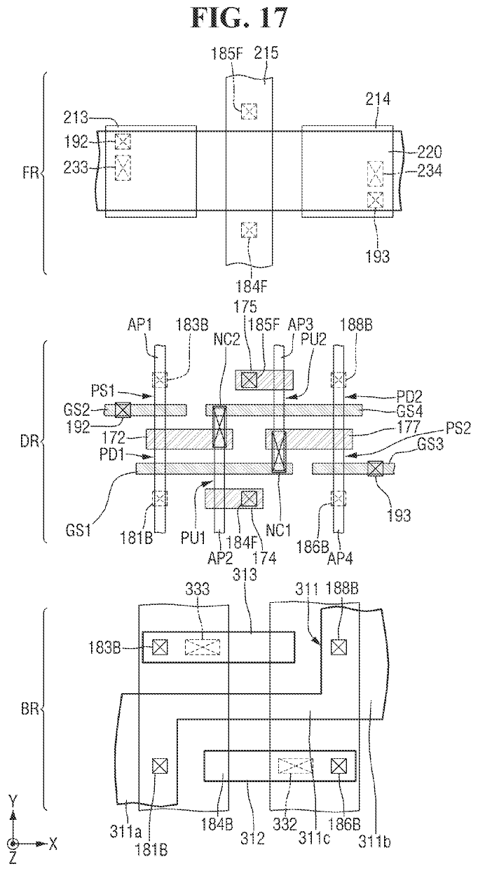

FIGS. 16 and 17 are layout diagrams for explaining an example of a semiconductor device. For simplicity of description, redundant parts of the description made with reference to FIGS. 1 to 15 are recapitulated or omitted.

Referring to FIGS. 1 and 16, in the semiconductor device, the first active pattern AP1 and the fourth active pattern AP4 are used as the channel region of the PFET, and the second active pattern AP2 and the third active pattern AP3 are used as the channel region of the NFET.

The first active pattern AP1 intersecting the first gate structure GS1 may be provided as the channel region of the first pull-up transistor PU1, and the second active pattern AP2 intersecting the first gate structure GS1 may be provided as the channel region of the first pull-down transistor PD1.

The fourth active pattern AP4 intersecting the fourth gate structure GS4 may be provided as the channel region of the second pull-up transistor PU2, and the third active pattern AP3 intersecting the fourth gate structure GS4 may be provided as the channel region of the second pull-down transistor PD2.

The sixth front wiring pattern 215 may be provided as the ground node V_{SS} for applying the first power voltage to the first pull-down transistor PD1 and the second pull-down transistor PD2 through the fourth source/drain contact 174 and the fifth source/drain contact 175.

The first back wiring pattern 311 may be provided as the power node V_{DD} for applying the second power voltage to the first pull-up transistor PU1 and the second pull-up transistor PU2.

Referring to FIGS. 1 and 17, the semiconductor device includes the source/drain contacts 172, 174, 175, and 177.

The source/drain contacts 172, 174, 175, and 177 may not overlap the back source/drain contacts 181B, 183B, 186B, and 188B in the third direction Z. For example, the first source/drain contact 171, the third source/drain contact 173, the sixth source/drain contact 176, and the eighth source/drain contact 178 of FIG. 12 may be omitted as the dummy source/drain contacts.

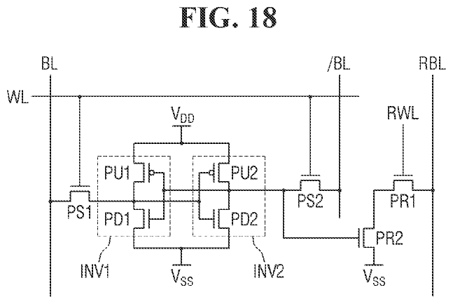

FIG. 18 is a circuit diagram illustrating an example of a semiconductor device. For simplicity of description, redundant parts of the description made with reference to FIG. 1 are recapitulated or omitted.

Referring to FIG. 18, the semiconductor device further includes a first readout transistor PR1 and a second readout transistor PR2 connected in series between a readout bit line RBL and the ground node V_{SS}.

The first readout transistor PR1 may be connected to the readout bit line RBL. The gate of the first readout transistor PR1 may be connected to a readout word line RWL. The gate of the second readout transistor PR2 may be connected to the output node of the second inverter INV2.

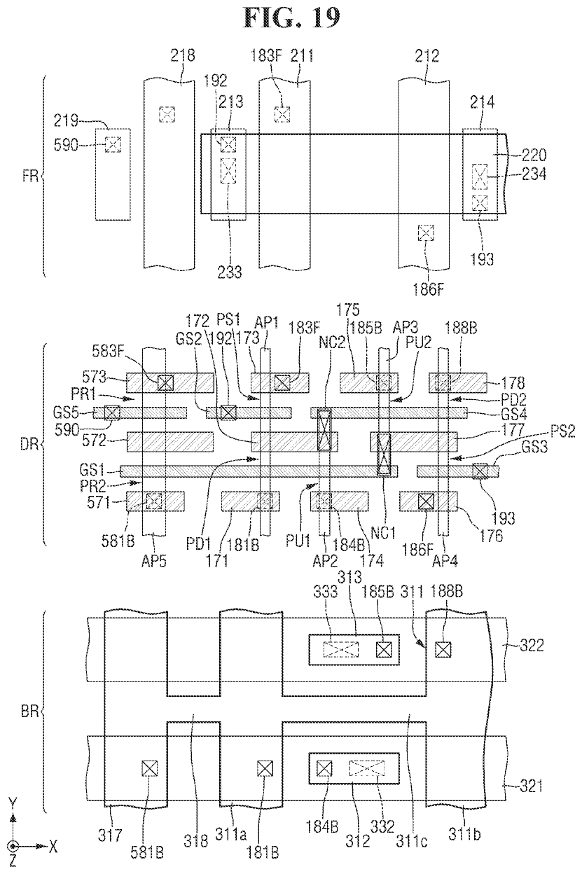

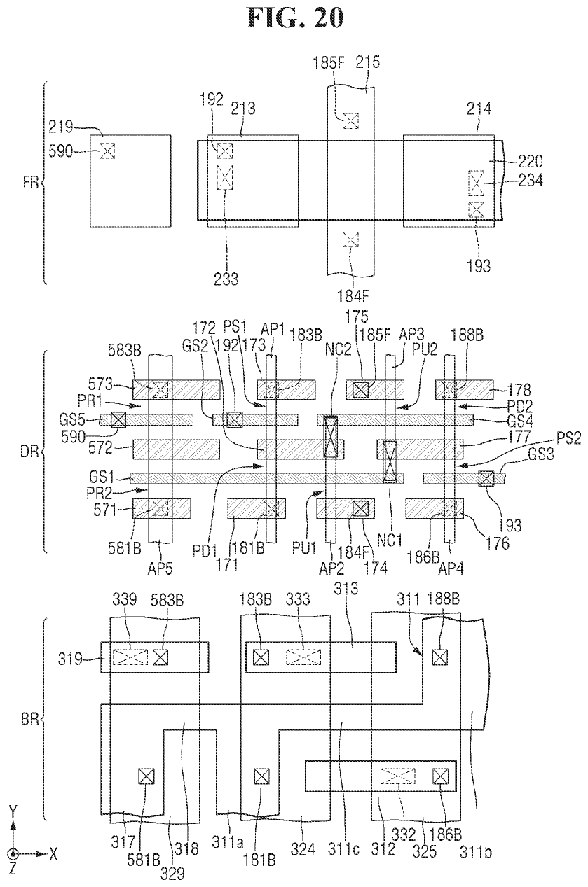

FIGS. 19 and 20 are layout diagrams for explaining an example of a semiconductor device. For simplicity of description, redundant parts of the description made with reference to FIGS. 1 to 18 are recapitulated or omitted.

Referring to FIGS. 18 to 20, the semiconductor device further includes a fifth active pattern AP5, a fifth gate structure GS5, and ninth to eleventh source/drain contacts 571 to 573.

The fifth active pattern AP5 may extend parallel to the first to fourth active patterns AP1 to AP4. The first gate structure GS1 may intersect the first active pattern AP1, the second active pattern AP2, and the fifth active pattern AP5. The first gate structure GS1 may be provided as the gate of the second readout transistor PR2. For example, the fifth active pattern AP5 intersecting the first gate structure GS1 may be provided as the channel region of the second readout transistor PR2.

The fifth gate structure GS5 may be spaced apart from the first gate structure GS1 in the first direction Y. In addition, the fifth gate structure GS5 may be spaced apart from the second gate structure GS2 in the second direction X. The fifth gate structure GS5 may extend parallel to the first gate structure GS1 and intersect the fifth active pattern AP5. The fifth gate structure GS5 may be provided as the gate of the first readout transistor PR1. For example, the fifth active pattern AP5 intersecting the fifth gate structure GS5 may be provided as the channel region of the first readout transistor PR1.

The ninth to eleventh source/drain contacts 571 to 573 may be connected to the fifth active pattern AP5. The ninth to eleventh source/drain contacts 571 to 573 may be sequentially arranged along the first direction Y. The tenth source/drain contact 572 may be interposed between the first gate structure GS1 and the fifth gate structure GS5. The first gate structure GS1 may be interposed between the ninth source/drain contact 571 and the tenth source/drain contact 572. The fifth gate structure GS5 may be interposed between the tenth source/drain contact 572 and the eleventh source/drain contact 573.

Referring to FIGS. 18 and 19, in the semiconductor device, first level front wiring patterns 211 to 214, 218, and 219 of the front region FR further include a seventh front wiring pattern 218 and an eighth front wiring pattern 219, and first level back wiring patterns 311 to 313, 317, and 318 of the back region BR further include a ninth back wiring pattern 317 and a tenth back wiring pattern 318. For simplicity of description, redundant parts of the description made with reference to FIG. 2 are recapitulated or omitted.

The seventh front wiring pattern 218 may be connected to the eleventh source/drain contact 573. For example, a fifth contact via 583F may be formed to connect the eleventh source/drain contact 573 to the seventh front wiring pattern 218. The seventh front wiring pattern 218 may be provided as the readout bit line RBL and may be connected to the first readout transistor PR1 through the eleventh source/drain contact 573. In some implementations, the seventh front wiring pattern 218 may be elongated in the first direction Y.

The eighth front wiring pattern 219 may be connected to the fifth gate structure GS5. For example, a third gate contact 590 may be formed to connect the gate electrode 130 of the third gate structure GS3 to the eighth front wiring pattern 219. The eighth front wiring pattern 219 may be provided as the readout word line RWL to be connected to the gate of the first readout transistor PR1.

The ninth back wiring pattern 317 may be connected to the source/drain region of the fifth active pattern AP5 with the first gate structure GS1 disposed between the source/drain region and the tenth source/drain contact 572. For example, a seventh back source/drain contact 581B with the first gate structure GS1 disposed between the seventh back source/drain contact 581B and the tenth source/drain contact 572 may be formed. The seventh back source/drain contact 581B may connect the fifth active pattern AP5 to the ninth back wiring pattern 317. The ninth back wiring pattern 317 may be provided as the ground node V_{SS} for applying the first power voltage to the second readout transistor PR2. In some implementations, the ninth back wiring pattern 317 may be elongated in the first direction Y.

The tenth back wiring pattern 318 may extend in the second direction X to connect the ninth back wiring pattern 317 to the first back wiring pattern 311. In some implementations, unlike the illustrated example, the tenth back wiring pattern 318 may be omitted. That is, the ninth back wiring pattern 317 may be spaced apart from the first back wiring pattern 311 in the second direction X.

Referring to FIGS. 18 and 20, in the semiconductor device, first level front wiring patterns 211 to 214 and 219 of the front region FR further include an eighth front wiring pattern 219, first level back wiring patterns 311 to 313 and 317 to 319 of the back region BR further include ninth to eleventh back wiring patterns 317 to 319, and second level back wiring patterns 324, 325, and 329 of the back region BR further include a twelfth back wiring pattern 329. For simplicity of description, redundant parts of the description made with reference to FIG. 12 are recapitulated or omitted.

The eighth front wiring pattern 219, the ninth back wiring pattern 317, and the tenth back wiring pattern 318 are similar to those described above with reference to FIG. 19, and thus a detailed description thereof is omitted.

The eleventh back wiring pattern 319 may be connected to the source/drain region of the fifth active pattern AP5 with the fifth gate structure GS5 disposed between the source/drain region and the tenth source/drain contact 572. For example, an eighth back source/drain contact 583B with the fifth gate structure GS5 disposed between the eighth back source/drain contact 583B and the tenth source/drain contact 572 may be formed. The eighth back source/drain contact 583B may connect the fifth active pattern AP5 to the eleventh back wiring pattern 319.

The twelfth back wiring pattern 329 may be connected to the eleventh back wiring pattern 319. For example, a third back via pattern 339 may be formed to extend in the third direction Z and connect the eleventh back wiring pattern 319 to the twelfth back wiring pattern 329. The twelfth back wiring pattern 329 may be provided as the readout bit line RBL and may be connected to the first readout transistor PR1 through the eleventh back wiring pattern 319. In some implementations, the twelfth back wiring pattern 329 may be elongated in the first direction Y.

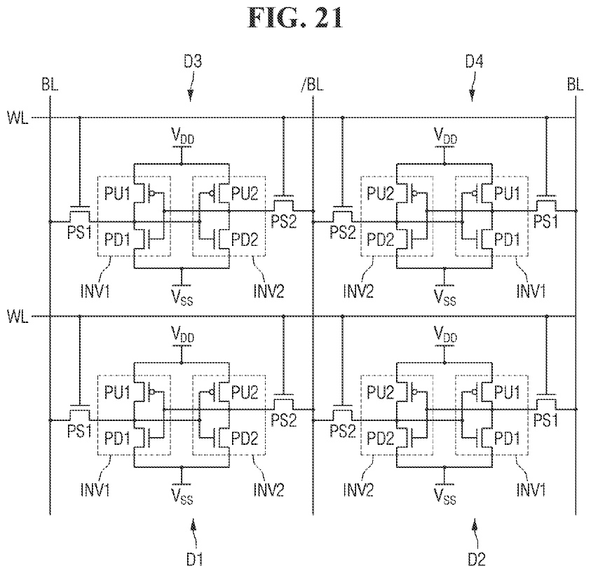

FIG. 21 is a circuit diagram illustrating an example of a semiconductor device. For simplicity of description, redundant parts of the description made with reference to FIG. 1 are recapitulated or omitted.

Referring to FIG. 21, the semiconductor device includes first to fourth unit elements D1 to D4 that are adjacent to each other.

Each of the first to fourth unit elements D1 to D4 may include a pair of inverters INV1 and INV2 connected in parallel between the power node V_{DD} and the ground node V_{SS}, and the first pass transistor PS1 and the second pass transistor PS2 connected to the output nodes of the inverters INV1 and INV2, respectively.

In some implementations, the first to fourth unit elements D1 to D4 may share one complementary bit line/BL. For example, two bit lines BL extending parallel to each other may be formed to both sides of one complementary bit line/BL. The first unit element D1 and the third unit element D3 may be defined between one of the two bit lines BL and the complementary bit line/BL, and the second unit element D2 and the fourth unit element D4 may be defined between the other of the two bit lines BL and the complementary bit line/BL.

In some implementations, the first unit element D1 and the second unit element D2 may share one word line WL, and the third unit element D3 and the fourth unit element D4 may share another word line WL.

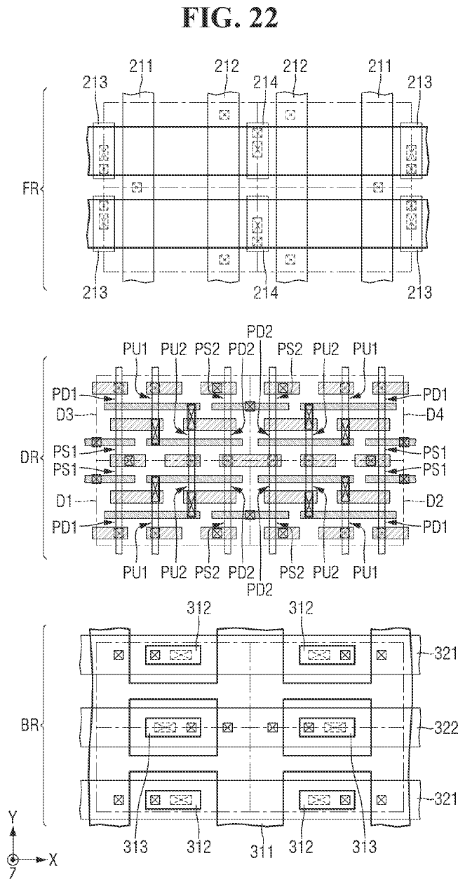

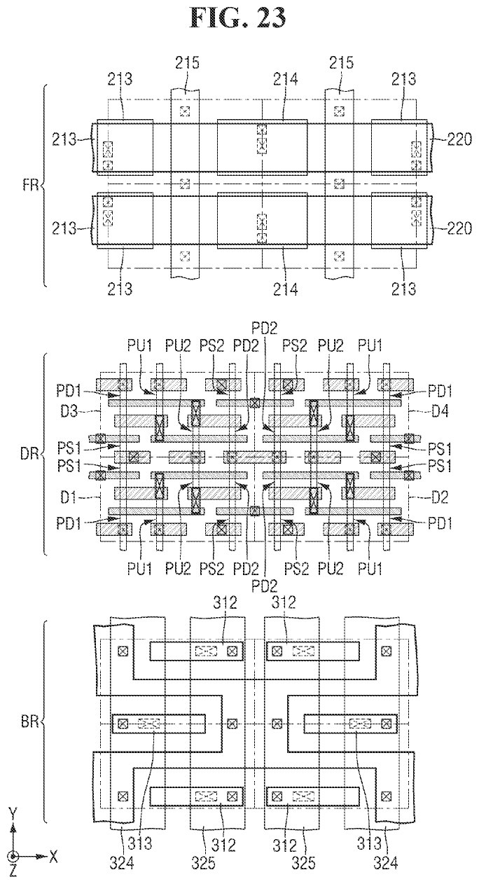

FIGS. 22 and 23 are layout diagrams for explaining an example of a semiconductor device. For simplicity of description, redundant parts of the description made with reference to FIGS. 1 to 21 are recapitulated or omitted hereinbelow.

Referring to FIGS. 21 to 23, in the semiconductor device, each of the first to fourth unit elements D1 to D4 includes the element region DR, the front region FR, and the back region BR. Each of the first to fourth unit elements D1 to D4 of FIG. 22 is the same as that described above with reference to FIG. 2, and thus a detailed description thereof is omitted. In addition, each of the first to fourth unit elements D1 to D4 of FIG. 23 is the same as that described above with reference to FIG. 12, and thus a detailed description thereof is omitted.

The first unit element D1 and the second unit element D2 may be arranged in a plane-symmetric relationship with respect to a plane (i.e., YZ plane) intersecting the second direction X. The third unit element D3 and the fourth unit element D4 may be arranged in a plane-symmetric relationship with respect to a plane (i.e., YZ plane) intersecting the second direction X. The first unit element D1 and the third unit element D3 may be arranged in a plane-symmetric relationship with respect to a plane (i.e., XZ plane) intersecting the first direction Y. The second unit element D2 and the fourth unit element D4 may be arranged in a plane-symmetric relationship with respect to a plane (i.e., XZ plane) intersecting the first direction Y.

The first extension portion 311a and the second extension portion 311b of the first back wiring pattern 311 may be alternately and repeatedly arranged in the second direction X. In addition, the connection portion 311c of the first back wiring pattern 311 may be repeatedly arranged along the first direction Y between the first extension portion 311a and the second extension portion 311b. The first back wiring pattern 311 may provide a wiring pattern having a substantially mesh shape. For example, as shown in FIG. 22, the first back wiring pattern 311 may provide a wiring pattern in a lattice mesh shape. Alternatively, for example, as shown in FIG. 23, the first back wiring pattern 311 may provide a wiring pattern in a zigzag mesh shape.

The second back wiring pattern 312 and the third back wiring pattern 313 may be alternately and repeatedly arranged in the first direction Y. The connection portion 311c of the first back wiring pattern 311 may be disposed between the second back wiring pattern 312 and the third back wiring pattern 313 that are repeatedly arranged. The second back wiring pattern 312 and the third back wiring pattern 313 may be disposed in openings of the first back wiring pattern 311 having a substantially mesh shape.

As a semiconductor device becomes more highly integrated, individual circuit patterns have become more miniaturized to realize more semiconductor devices within the same area. For this purpose, a backside power delivery network (BSPDN), which places a power delivery network on the backside of a substrate, has been studied.

The semiconductor device according to some implementations may improve design freedom and integration density of the semiconductor device by efficiently using the backside power delivery network. Specifically, as described above, the first back wiring pattern 311 of the back region BR may be provided in a substantially mesh shape across a plurality of elements. The first back wiring pattern 311 may reduce electrical resistance compared to wiring patterns formed separately for each element. In addition, the second back wiring pattern 312 and the third back wiring pattern 313 of the back region BR may be disposed within the openings of the first back wiring pattern 311 having a substantially mesh shape. The second back wiring pattern 312 and the third back wiring pattern 313 may provide a connection path between elements and other back wiring patterns (e.g., the second level back wiring patterns) disposed at different levels, thereby allowing efficient utilization of the back region BR. Accordingly, the semiconductor device with improved design freedom and integration density may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the present scope of the technology described herein has been particularly shown and described with reference to example implementations thereof, it will be understood by those of ordinary skill in the art that various changes in form and details may be made therein without departing from the spirit and scope of the technology as defined by the following claims. It is therefore desired that the present implementations be considered in all respects as illustrative and not restrictive, reference being made to the appended claims rather than the foregoing description to indicate the scope of the technology.

1. A semiconductor device comprising:
a substrate comprising a first surface and a second surface opposite to the first surface;
a first active pattern on the first surface of the substrate;
a first gate structure intersecting the first active pattern; and
a first back wiring pattern and a second back wiring pattern disposed on the second surface of the substrate at a same height with respect to the substrate,
wherein the first back wiring pattern comprises a first extension portion and a second extension portion, each extension portion of the first extension portion and the second extension portion extending in a first direction, a connection portion extending in a second direction intersecting the first direction, and the connection portion configured to connect the first extension portion with the second extension portion, and
wherein the second back wiring pattern is spaced apart from the first extension portion in the second direction, and the second back wiring pattern is spaced apart from the connection portion in the first direction.

2. The semiconductor device of claim 1, comprising a first back source/drain contact extending through the substrate, wherein the first back source/drain contact is configured to connect a first source/drain region of the first active pattern with the first extension portion.

3. The semiconductor device of claim 2, comprising:
a second active pattern on the first surface of the substrate, the second active pattern parallel to the first active pattern and intersecting the first gate structure; and
a second back source/drain contact extending through the substrate and configured to connect a second source/drain region of the second active pattern with the second back wiring pattern.

4. The semiconductor device of claim 2, comprising:
a second active pattern, parallel to the first active pattern, on the first surface of the substrate;
a second gate structure intersecting the second active pattern; and
a second back source/drain contact extending through the substrate and configured to connect a second source/drain region of the second active pattern with the second extension portion.

5. The semiconductor device of claim 1, comprising a first front wiring pattern and a second front wiring pattern disposed on the first surface of the substrate at a same height with respect to the substrate,
wherein the first front wiring pattern extends in the first direction, and
wherein the second front wiring pattern is spaced apart from the first front wiring pattern in the second direction.

6. The semiconductor device of claim 5, comprising:
a second gate structure parallel to the first gate structure and intersecting the first active pattern;
a first source/drain contact connected with the first active pattern and between the first gate structure and the second gate structure; and
a second source/drain contact connected with the first active pattern, the second gate structure disposed between the second source/drain contact and the first source/drain contact,
wherein the second gate structure is connected with the second front wiring pattern, and
wherein the second source/drain contact is connected with the first front wiring pattern.

7. The semiconductor device of claim 1, wherein the second back wiring pattern is interposed between the first extension portion and the second extension portion in the second direction.

8. The semiconductor device of claim 1, wherein the second extension portion does not overlap the second back wiring pattern in the second direction.

9. The semiconductor device of claim 1, comprising a third back wiring pattern disposed on the second surface of the substrate at a same height as the first back wiring pattern and the second back wiring pattern with respect to the substrate,
wherein the third back wiring pattern is spaced apart from the second extension portion in the second direction, and the third back wiring pattern is spaced apart from the connection portion in the first direction, and
wherein the connection portion is interposed between the second back wiring pattern and the third back wiring pattern.

10. The semiconductor device of claim 1, comprising:
a third back wiring pattern on the second surface of the substrate and higher than the first back wiring pattern and the second back wiring pattern with respect to the substrate; and
a back via pattern configured to connect the second back wiring pattern with the third back wiring pattern.

11. A semiconductor device comprising:
a substrate comprising a first surface and a second surface opposite to the first surface;
a first active pattern and a second active pattern on the first surface of the substrate, the second active pattern parallel to the first active pattern;
a first gate structure intersecting the first active pattern and the second active pattern;
a first back wiring pattern, a second back wiring pattern, and a third back wiring pattern disposed on the second surface of the substrate at a same height with respect to the substrate and spaced apart from each other;
a first back source/drain contact configured to connect a first source/drain region of the first active pattern with the first back wiring pattern;
a second back source/drain contact configured to connect a second source/drain region of the second active pattern with the second back wiring pattern;
a fourth back wiring pattern on the second surface of the substrate and higher than the first back wiring pattern, the second back wiring pattern, and the third back wiring pattern with respect to the substrate; and
a first back via pattern configured to connect the second back wiring pattern with the fourth back wiring pattern,
wherein the first back wiring pattern comprises a first extension portion and a second extension portion, each extension portion of the first extension portion and the second extension portion extending in a first direction, a connection portion extending in a second direction intersecting the first direction, and the connection portion configured to connect the first extension portion with the second extension portion, and
wherein the connection portion is interposed between the second back wiring pattern and the third back wiring pattern in the first direction.

12. The semiconductor device of claim 11, wherein each back wiring pattern of the second back wiring pattern and the third back wiring pattern is interposed between the first extension portion and the second extension portion.

13. The semiconductor device of claim 11, wherein the second back wiring pattern does not overlap the second extension portion in the second direction, and
wherein the third back wiring pattern does not overlap the first extension portion in the second direction.

14. The semiconductor device of claim 11, wherein a first power voltage is applied to the first back wiring pattern, and
wherein a second power voltage different from the first power voltage is applied to the fourth back wiring pattern.

15. The semiconductor device of claim 11, wherein the second back wiring pattern and the third back wiring pattern are alternately and repeatedly arranged along the first direction.

16.-20. (canceled)

21. A semiconductor device comprising:
a substrate comprising a first surface and a second surface opposite to the first surface;
a first active pattern, a second active pattern, a third active pattern, and a fourth active pattern, parallel to each other, on the first surface of the substrate;
a first gate structure intersecting the first active pattern and the second active pattern;
a second gate structure parallel to the first gate structure and intersecting the first active pattern;
a third gate structure spaced apart from the first gate structure and intersecting the fourth active pattern;
a fourth gate structure parallel to the third gate structure and intersecting the third active pattern and the fourth active pattern;
a first source/drain contact configured to connect the first active pattern with the second active pattern, the first source/drain contact between the first gate structure and the second gate structure;
a second source/drain contact configured to connect the third active pattern with the fourth active pattern, the second source/drain contact between the third gate structure and the fourth gate structure;
a first shared contact configured to connect the first gate structure with the second source/drain contact;
a second shared contact configured to connect the fourth gate structure with the first source/drain contact;
a first back source/drain contact extending through the substrate to be connected with the first active pattern, the first gate structure disposed between the first back source/drain contact and the first source/drain contact;
a second back source/drain contact extending through the substrate to be connected with the fourth active pattern, the fourth gate structure disposed between the second back source/drain contact and the second source/drain contact; and
a first back wiring pattern, a second back wiring pattern, and a third back wiring pattern disposed on the second surface of the substrate at a same height with respect to the substrate and spaced apart from each other,
wherein the first back wiring pattern comprises a first extension portion and a second extension portion, each extension portion of the first extension portion and the second extension portion extending in a first direction, a connection portion extending in a second direction intersecting the first direction, and the connection portion configured to connect the first extension portion with the second extension portion,
wherein the connection portion is interposed between the second back wiring pattern and the third back wiring pattern in the first direction, and
wherein the first back source/drain contact and the second back source/drain contact are connected with the first back wiring pattern.

22. The semiconductor device of claim 21, comprising:
a third back source/drain contact extending through the substrate to be connected with the second active pattern, the first gate structure disposed between the third back source/drain contact and the first source/drain contact; and
a fourth back source/drain contact extending through the substrate to be connected with the third active pattern, the fourth gate structure disposed between the fourth back source/drain contact and the second source/drain contact,
wherein the third back source/drain contact is connected with the second back wiring pattern, and
wherein the fourth back source/drain contact is connected with the third back wiring pattern.

23. The semiconductor device of claim 21, wherein a part of the second back wiring pattern overlaps the second extension portion in the first direction, and
wherein a part of the third back wiring pattern overlaps the first extension portion in the first direction.

24. The semiconductor device of claim 23, comprising:
a third back source/drain contact extending through the substrate to be connected with the first active pattern, the second gate structure disposed between the third back source/drain contact and the first source/drain contact; and
a fourth back source/drain contact extending through the substrate to be connected with the fourth active pattern, the third gate structure disposed between the fourth back source/drain contact and the second source/drain contact,
wherein the third back source/drain contact is connected with the third back wiring pattern, and
wherein the fourth back source/drain contact is connected with the second back wiring pattern.

25. The semiconductor device of claim 21, wherein each active pattern of the first active pattern, the second active pattern, the third active pattern, and the fourth active pattern extends in the first direction, and
wherein each gate structure of the first gate structure, the second gate structure, the third gate structure, and the fourth gate structure extends in the second direction.

26. (canceled)
